(19) United States
(12) Patent Application Publication
(10) Pub. No.: US 2026/0254194 A1
(43) Pub. Date: Aug. 27, 2026

(54) LASER EMITTING DEVICE

(71) Applicants: National Chung Cheng University, Chiayi County (TW); iReach Corporation, Hsinchu County (TW)

(72) Inventors: Zhi-Ting Ye, Hsinchu County (TW); Tzu-Chieh Hsu, Hsinchu County (TW); Chun-Yi Lee, Hsinchu County (TW)

(21) Appl. No.: 19/055,983

(22) Filed: Feb. 18, 2025

(51) Int. Cl. H01S 5/0233; H01S 5/024; H01S 5/40

(52) U.S. Cl. CPC H01S 5/0233; H01S 5/02469; H01S 5/4025

(57) ABSTRACT

The present application provides a laser emitting device, which comprises a substrate with two electrodes underneath, a pattern layer set above the substrate, and a plurality of laser emitting arrays individually disposed on the pattern layer. Each of the laser emitting arrays includes a heat-conductive substrate, a connection layer, a plurality of laser emitting components, a shading component, and a sealant. The plurality of laser emitting components are formed on a preparative substrate and are removed by chemical etching. The plurality of laser emitting components are then individually disposed on the connection layer and connected to the heat-conductive substrate, forming the laser emitting arrays. Finally, the laser emitting arrays are disposed on the pattern layer, for forming the laser emitting device.

### FIELD OF THE INVENTION

The present application relates to a laser emitting device, particularly to a laser emitting device with improving heat dissipation efficiency.

### BACKGROUND OF THE INVENTION

The edge-emitting laser (EEL) has been a primary framework in laser technology for a long term. Although the manufacturing technology of edge-emitting lasers is mature and widely used in many fields, such as optical communication, optical sensing, and optical storage, however, EELs have inherent drawbacks, such as complex manufacturing processes, the requirement for precise alignment, and the emission of laser beams parallel to the substrate surface, resulting in lowering optical coupling efficiency.

To resolve the issues of edge-emitting lasers, the vertical-cavity surface-emitting laser (VCSEL) has been developed as a potential replacement technology of EEL. The VCSEL is mainly characterized in that its laser beam emits perpendicular to the substrate surface, and offering several advantages including optical coupling simplified, feasibility of array production, lower energy consumption, reduced manufacturing costs, and the benefit of monolithic processing, further simplifying the manufacturing process.

However, despite the structural advantages of VCSELs, existing technologies still face challenges, particularly in terms of heat dissipation performance. In well-known technologies, the poor heat dissipation of VCSELs is significant, especially in high-power applications, wherein heat of VCSELs cannot be effectively expelled, leading to component overheating. Overheating results in decreased laser performance, including reduced output power, wavelength shift, and even shortened component lifespan. Therefore, effectively improving the heat dissipation performance of VCSELs remains a significant challenge in existing technologies.

Furthermore, as the application scope expands, the existing VCSEL technology has encountered bottlenecks in terms of laser beam quality, output power, wavelength range, and energy efficiency. In many high-demand applications, the existing structures and designs cannot fully meet the requirements, thus further optimization of the VCSEL structure, especially in terms of heat management, has become a crucial issue in current technological research.

In view of the aforementioned problems with the known technology, the present application provides an improved VCSEL structure that overcomes the poor heat dissipation of the known technology, enhances its heat management performance, and thereby improves overall performance and application scope.

### SUMMARY OF THE INVENTION

An objective of the present application is to provide a laser emitting device, wherein a plurality of laser emitting components of a plurality of laser arrays are first formed on a preparative substrate, the preparative substrate is then removed, and the plurality of laser emitting components are individually disposed on a substrate with higher thermal conductivity, finally packaging the laser arrays to form a laser emitting device with higher heat dissipation efficiency.

To achieve the various objectives and effects mentioned above, the present application provides a laser emitting device, which includes two electrodes disposed beneath a substrate, a pattern layer disposed on the substrate electrically connecting the two electrodes, a plurality of laser emitting arrays individually disposed on the pattern layer, each of the laser emitting arrays comprising a heat-conductive substrate disposed on the pattern layer, a connection layer disposed on the heat-conductive substrate, a plurality of laser emitting components individually disposed on the connection layer, a shading component disposed on the substrate, the shading component circularly arranged around the outside of the laser emitting arrays, a sealing compound disposed inside the shading component covering the laser emitting arrays. The plurality of laser emitting components are formed on a preparative substrate, which is removed by chemical etching, then the plurality of laser emitting components are individually disposed on the connection layer and connected to the heat-conductive substrate to form the laser emitting arrays. Finally, the laser emitting arrays are disposed on the pattern layer to form the laser emitting device. An isolation area is set between the two electrodes, and the area summation of the two electrodes and the isolation area equals an area of the substrate; this structure enhances the heat dissipation efficiency of the laser emitting device.

In one embodiment of the present application, the interval between the individual laser emitting components of the laser emitting arrays decreases from the outside towards the inside.

In one embodiment of the present application, the chemical etching involves using a solution of ammonium hydroxide (NH₄OH) and hydrogen peroxide (H₂O₂) to remove the preparative substrate within a specific time.

In one embodiment of the present application, the duration for the chemical etching is between 20 to 35 minutes.

In one embodiment of the present application, a material of the substrate is selected from a group consisting of aluminum nitride (AlN), alumina, and silicon carbide (SiC).

In one embodiment of the present application, a material of the heat-conductive substrate is selected from a group consisting of copper (Cu), tungsten (W) and molybdenum (Mo).

In one embodiment of the present application, the sealing compound is silicone.

In one embodiment of the present application, the area of one of the two electrodes is equal to or greater than the 50% area of the substrate.

In one embodiment of the present application, each of the laser emitting devices individually comprises a first reflector, disposed on the connection layer; a light-emitting layer, disposed on the first reflector; an oxide layer, disposed on the light-emitting layer; a second reflector, disposed on the oxide layer; an insulating layer, covering the outside of the first reflector, the light-emitting layer, the oxide layer, and the second reflector; and an electrode layer, disposed on the insulating layer.

In one embodiment of the present application, the ratio of the first height of the sealant to the second height of the laser emitting arrays is between 1.1 and 1.5.

### BRIEF DESCRIPTION OF DRAWINGS

FIG. 1A to FIG. 1B which are schematic diagrams of the structure of the laser emitting device according to the present application;

FIG. 2 which is a schematic diagram showing the interval changes of the plurality of laser emitting components according to the present application;

FIG. 3 which is a schematic diagram of the structure of the plurality of laser emitting components according to the present application;

FIG. 4A to FIG. 4C which are schematic diagrams of the substrate transfer of the laser emitting device according to the present application; and

FIG. 5 which is a schematic diagram of the height of the laser emitting device according to the present application.

### DETAILED DESCRIPTION

In view of the problems of the known technology, the present application provides a laser emitting device, which comprises two electrodes disposed below a substrate, a pattern layer disposed on the substrate, and a plurality of laser emitting arrays individually disposed on the pattern layer. Each of the laser emitting arrays includes a heat-conductive substrate, a connection layer, a plurality of laser emitting components, a shading component, and sealanta. The plurality of laser emitting components are initially formed on a preparative substrate, then the preparative substrate is removed by chemical etching, and thereafter, the plurality of laser emitting components are individually disposed on the connection layer and connected to the heat-conductive substrate. Finally, the laser emitting arrays are disposed on the pattern layer to form the laser emitting device, thereby moving the plurality of laser emitting components to a substrate with better heat dissipation and encapsulating them, solving the problem of poor heat dissipation in known VCSELs.

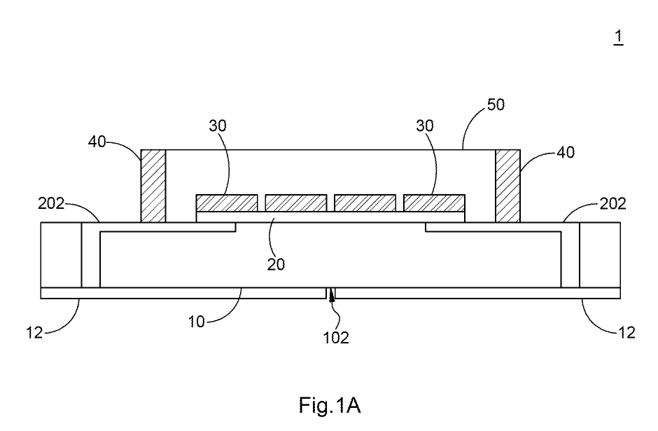

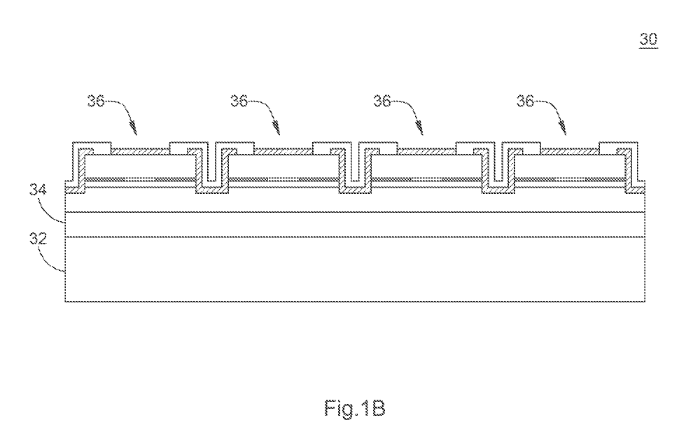

Please refer to FIG. 1A to FIG. 1B, which are schematic diagrams of the laser emitting device according to the present application. As shown in the figures, this embodiment is the first embodiment, and it is a laser emitting device 1, comprising a substrate 10, a pattern layer 20, a plurality of laser emitting arrays 30, a shading component 40, and sealant 50.

Refer to FIG. 1A to FIG. 1B again, as shown in the figures, in this embodiment, two electrodes 12 are disposed beneath the substrate 10, the pattern layer 20 is disposed on the substrate 10, and electrically connects to the two electrodes 12. Each of the laser emitting arrays 30 is individually disposed on the pattern layer 20, where each laser emitting array 30 includes a thermally conductive substrate 32, a connection layer 34, and a plurality of laser emitting components 36. The thermally conductive substrate 32 is disposed on the pattern layer 20, the connection layer 34 is disposed on the thermally conductive substrate 32, and the plurality of laser emitting components 36 are individually disposed on the connection layer 34. The shading component 40 is disposed on the substrate 10, encircling the outside of the laser emitting arrays 30, and the sealant 50 is disposed inside the shading component 40, covering the laser emitting arrays 30.

Continued to the above, in this embodiment, the pattern layer 20 includes a circuit 202 to pass through the substrate 10, connecting the circuit 202 of the pattern layer 20 to the two electrodes 12.

Continued to the above, in this embodiment, the material of the substrate 10 is selected from a group consisting of aluminum nitride (AlN), alumina, and silicon carbide (SiC).

Continued from the above, in this embodiment, the material of the thermally conductive substrate 32 is selected from a group consisting of copper (Cu), tungsten (W), and molybdenum (Mo), preferably, the material of the thermally conductive substrate 32 is selected from copper tungsten (CuW) in this embodiment.

Continued to the above, in this embodiment, the sealant 50 is silicone.

Continued to the above, in this embodiment, the two electrodes 12 cover the underside of the substrate 10, with the two electrodes 12 covering the substrate 10 as much as possible, and an isolation area 102 is set between the two electrodes 12. The total area of the two electrodes 12 and the isolation area 102 equals the area of the underside surface of the substrate 10, ensuring that the two electrodes 12 do not touch each other and are spaced apart to prevent short-circuiting. The two electrodes 12 covering the substrate 10 utilize the material properties of the electrodes 12 to conduct the heat from the substrate 10, further enhancing the overall heat dissipation efficiency of the laser emitting device 1.

Continued to the above, in one embodiment, the area of one of the two electrodes 12 is equal to or greater than the 50% area of the substrate 10.

In this embodiment, the laser emitting device 1 places the individual laser emitting components 36 on the thermally conductive substrate 32 via the connection layer 34, rapidly conducting the heat emitted by the plurality of laser emitting components 36, addressing the known issue of poor heat dissipation in laser emitting devices.

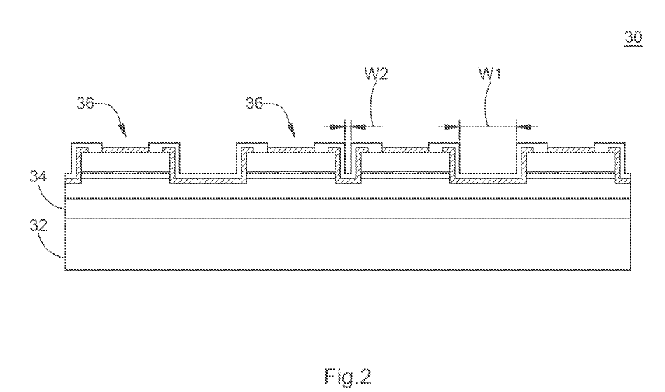

Please refer to FIG. 2, which is a schematic diagram of the structure of the laser emitting device according to the present application. As shown in the figure, this embodiment, based on the aforementioned first embodiment, features individual laser emitting components 36 of the laser emitting array 30 having intervals W1/W2, with the intervals W1/W2 decreasing from the outer to the inner side. As illustrated, the inner laser emitting components 36 have an interval W1, while the outer laser emitting components 36 have an interval W2, and the interval W1 is smaller than the interval W2.

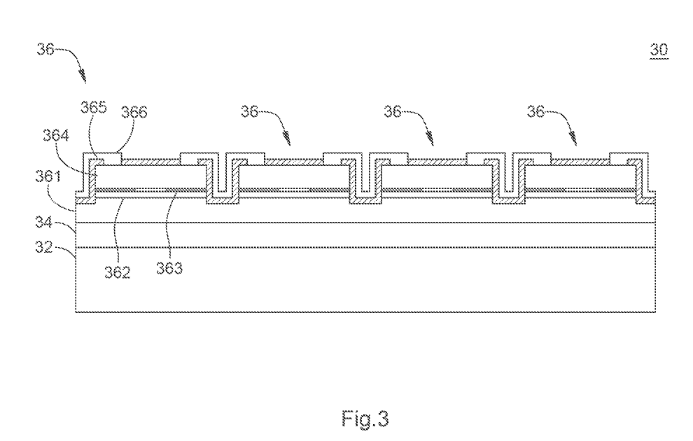

Please refer to FIG. 3, which is a schematic diagram of the structure of the plurality of laser emitting components according to the present application. As shown, this embodiment, based on the aforementioned first embodiment, includes individual laser emitting components 36 comprising: a first reflector 361, a light-emitting layer 362, an oxide layer 363, a second reflector 364, an insulating layer 365, and an electrode layer 366.

Referring to FIG. 3 again, as shown in the figure, in this embodiment, the first reflector 361 is disposed on the connection layer 34, the light-emitting layer 362 is disposed on the first reflector 361, the oxide layer 363 is disposed on the light-emitting layer 362, the second reflector 364 is disposed on the oxide layer 363, the insulating layer 365 encapsulates the first reflector 361, the light-emitting layer 362, the oxide layer 363, and the second reflector 364 on one side, and the electrode layer 366 is disposed on the insulating layer 365 and electrically connected to the light-emitting layer 362.

Continued to the above, in this embodiment, the first reflector 361 can be a Distributed Bragg Reflector (DBR), and similarly, the second reflector 364 can also be a Distributed Bragg Reflector.

Continued to the above, in this embodiment, the light-emitting layer 362 and the oxide layer 363 serve as the active layers of the laser emitting devices 36, which are used to generate light.

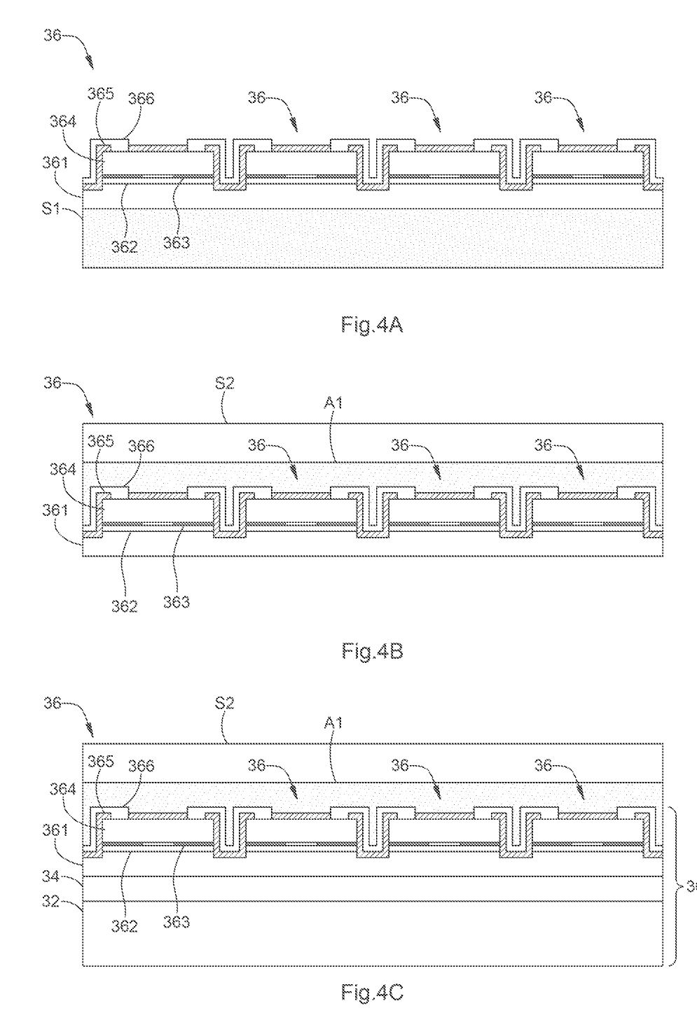

Referring to FIG. 3 and FIG. 4A to FIG. 4C again, FIG. 4A to FIG. 4C illustrate the substrate transfer diagrams of the laser emitting device according to the present application, as shown in the figure, this embodiment is based on the aforementioned first embodiment, in this embodiment,

Refer to FIG. 3 to FIG. 4C again, as shown, this embodiment is based on the aforementioned laser emitting device embodiment. In this embodiment, the plurality of laser emitting components 36 are first formed on a preparative substrate S1, such as a gallium arsenide (GaAs) substrate, to facilitate manufacturing. Then, a temporary substrate S2 with an adhesive layer A1 is disposed on the plurality of laser emitting components 36. After the adhesive layer A1 encapsulates/secures the plurality of laser emitting components 36, the preparative substrate S1 below is removed by chemical etching. Subsequently, the plurality of laser emitting components 36 are individually disposed on the connection layer 34 and connected to the heat-conductive substrate 32. Then, the laser emitting arrays 30 are disposed on the pattern layer 20. Finally, the adhesive layer A1 and the temporary substrate S2 are removed to form the laser emitting arrays 30, thus completing the substrate replacement. This transfers the plurality of laser emitting components 36 from a substrate with lower thermal conductivity to one with higher thermal conductivity, thereby manufacturing the laser emitting arrays 30 and improving the overall heat dissipation efficiency.

Continued to the above, in this embodiment, the chemical etching uses an ammonium hydroxide (NH₄OH) and hydrogen peroxide (H₂O₂) solution to remove the preparative substrate S1 over a period of time.

Continued to the above, in one embodiment, the time for removing the preparative substrate S1 ranges from 20 to 35 minutes, although this embodiment is not limited to this range.

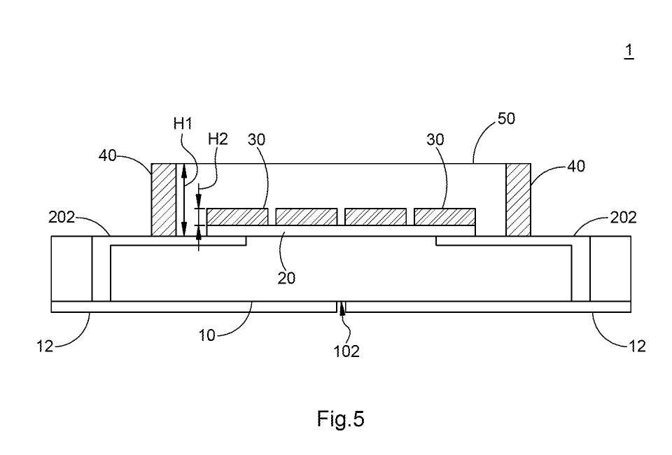

Refer to FIG. 5, which is a height schematic of the laser emitting device according to the present application. As shown, this embodiment is based on the aforementioned first embodiment. In this embodiment, due to the lower thermal conductivity of the material of the sealant 50, the height ratio between the sealant 50 and the laser emitting arrays 30 may further be in discussion. As shown, the sealant 50 has a first height H1, and the laser emitting arrays 30 have a second height H2. The ratio of the first height H1 to the second height H2 is from 1.1 to 1.5, achieving a better heat dissipation ratio between the laser emitting arrays 30 and the sealant 50.

Sum up, the present application provides a laser emitting device, where the plurality of laser emitting components are first formed on a preparative substrate, then the preparative substrate is removed, and the plurality of laser emitting components are disposed on a substrate with higher thermal conductivity to form a laser emitting array. Finally, the laser emitting array is packaged to create a laser emitting device with higher heat dissipation efficiency, overcoming the issues of VCSELs in high-power applications without dissipating heat effectively, leading to component overheating, reduced output power, wavelength shift, and even shortened component lifespan.

What is claimed is:

1. A laser emitting device, comprising:
a substrate, having two electrodes disposed below thereof;
a pattern layer, disposed on the substrate, electrically connecting the two electrodes;
a plurality of laser emitting arrays, each disposed on the pattern layer, each of the laser emitting arrays comprising:
a thermally conductive substrate, disposed on the pattern layer;
a connection layer, disposed on the thermally conductive substrate; and
a plurality of laser emitting components, each disposed on the connection layer;
a shading component, disposed on the substrate, the shading component being annularly disposed around the outside of the laser emitting arrays; and
a sealant, disposed inside the shading component, encapsulating the laser emitting arrays;
wherein, the plurality of laser emitting components are formed on a preparative substrate, removed by chemical etching, then each of the plurality of laser emitting components is individually disposed on the connection layer and connected to the thermally conductive substrate to form the laser emitting arrays, and finally, the laser emitting arrays are disposed on the pattern layer to form the laser emitting device; and
an isolation area, set between the two electrodes, the area summation of the two electrodes and the isolation area being equal to an area of the substrate.

2. The laser emitting device of claim 1, wherein an interval between each two laser emitting components of the laser emitting arrays is shrunken from the outer side to the inner side.

3. The laser emitting device of claim 1, wherein the chemical etching uses a solution of ammonium hydroxide (NH₄OH) and hydrogen peroxide (H₂O₂) to remove the pre-set substrate within a specific time.

4. The laser emitting device of claim 1, wherein the plurality of laser emitting components are first formed on the preparative substrate, a temporary substrate with an adhesive layer disposed on the plurality of laser emitting components, the plurality of laser emitting components are individually disposed on the connection layer and connected to the heat-conductive substrate, the laser emitting arrays disposed on the pattern layer, the adhesive layer and the temporary substrate are removed to form the laser emitting arrays, thus completing the substrate replacement.

5. The laser emitting device of claim 1, wherein a material of the substrate is selected from a group consisting of aluminum nitride (AlN), alumina, and silicon carbide (SiC).

6. The laser emitting device as claimed in claim 1, wherein a material of the thermally conductive substrate is selected from a group consisting of copper (Cu), tungsten (W), and molybdenum (Mo).

7. The laser emitting device of claim 1, wherein the sealant is silicone.

8. The laser emitting device of claim 1, wherein one of the two electrodes has an area equal to or greater than the 50% area of the substrate.

9. The laser emitting device of claim 1, wherein each of the plurality of laser emitting components individually comprises:
a first reflector, disposed on the connection layer;
a light-emitting layer, disposed on the first reflector;
an oxide layer, disposed on the light-emitting layer;
a second reflector, disposed on the oxide layer;
an insulating layer, covering the outside of the first reflector, the light-emitting layer, the oxide layer, and the second reflector; and
an electrode layer, disposed on the insulating layer.

10. The laser emitting device of claim 1, wherein the ratio of the first height of the sealant to the second height of the laser emitting arrays is from 1.1 to 1.5.
